(19) United States
(12) Patent Application Publication
(10) Pub. No.: US 2025/0203743 A1
(43) Pub. Date: Jun. 19, 2025

(54) LIGHT SOURCE DRIVING DEVICE AND LIGHT EMITTING DEVICE

(71) Applicant: SONY SEMICONDUCTOR SOLUTIONS CORPORATION, Kanagawa (JP)

(72) Inventors: Hiroyuki Yamamoto, Kumamoto (JP); Nobuaki KAJI, Kanagawa (JP)

(21) Appl. No.: 18/846,503

(22) PCT Filed: Apr. 21, 2023
(86) PCT No.: PCT/JP2023/016023

§ 371 Date: Sep. 12, 2024

(30) Foreign Application Priority Data
Apr. 28, 2022 (JP) 2022-075231

(51) Int. Cl. H05B 47/20

(52) U.S. Cl. CPC H05B 47/20

(57) ABSTRACT

Damage that has partially occurred in a light source is detected. A light source driving device according to the present disclosure includes a light source control unit and an abnormality detection unit. A light source control unit of the light source driving device performs control in which a plurality of light emitting units is divided into a plurality of regions in the light source in which a plurality of light emitting units is arranged, and the light emitting units are caused to emit light for each of the regions. An abnormality detection unit of the light source driving device detects abnormality of a light emitting unit for each of the regions based on a light reception signal from a light receiving unit that generates the light reception signal in accordance with light from the light source.

### FIELD

The present disclosure relates to a light source driving device and a light emitting device.

### BACKGROUND

A distance measuring device is used in a distance measuring device that measures a distance to an object. The distance measuring device applies light to the object, and detects reflected light from the object. The distance measuring device measures a distance by measuring a time during which light travels between the distance measuring device and the object. In such a distance measuring device, a light source that applies light to the object is disposed. This light source needs to apply light in a light amount (intensity) supporting a distance measurement range. A light source including a laser diode that generates laser light as a light emitting element is used as a light source of a distance measuring device supporting a relatively large distance measurement range.

Laser light having a high energy density is harmful to a human body. Thus, there is proposed a light source driving device that performs control in which an abnormality of a light emitting element is detected and light emission is stopped (e.g., see Patent Literature 1). The light source driving device includes a light source control unit and a light receiving unit. The light source control unit controls a light source of a laser diode. The light receiving unit receives light from the light source.

Then, the light source driving device stops control of light emission of the light source in the light source control unit when the light receiving unit detects an abnormality of the laser diode.

### CITATION LIST

### Patent Literature

Patent Literature 1: JP 2020-047874 A

### SUMMARY

### Technical Problem

A problem of the above-described technique is, however, that partial damage of a light source including a plurality of arranged light emitting units such as a vertical cavity surface emitting laser (VCSEL) cannot be detected.

Therefore, the present disclosure proposes a light source driving device and a light emitting device, which detect the partial damage of a light source.

### Solution to Problem

A light source driving device according to the present disclosure includes: a light source control unit that performs control in which a plurality of light emitting units is divided into a plurality of regions in a light source in which the plurality of light emitting units is arranged, and the light emitting units are caused to emit light for each of the regions; and an abnormality detection unit that detects abnormality of the light emitting units for each of the regions based on a light reception signal from a light receiving unit that generates the light reception signal in accordance with light from the light source.

### BRIEF DESCRIPTION OF DRAWINGS

FIG. 1 illustrates a configuration example of a light emitting device according to a first embodiment of the present disclosure.

FIG. 2A illustrates a configuration example of a light source according to the first embodiment of the present disclosure.

FIG. 2B illustrates a configuration example of the light source according to the first embodiment of the present disclosure.

FIG. 3 illustrates a configuration example of the light emitting device according to the embodiment of the present disclosure.

FIG. 4 illustrates an example of a light emission method of the light source according to the first embodiment of the present disclosure.

FIG. 5 illustrates an example of a threshold according to the first embodiment of the present disclosure.

FIG. 6 illustrates an example of a processing procedure of abnormality detection processing according to the first embodiment of the present disclosure.

FIG. 7 illustrates an example of a processing procedure of light receiving processing according to the first embodiment of the present disclosure.

FIG. 8 illustrates an example of a processing procedure of abnormality processing according to the first embodiment of the present disclosure.

FIG. 9A illustrates an arrangement example of a light receiving unit according to the second embodiment of the present disclosure.

FIG. 9B illustrates an arrangement example of the light receiving unit according to the second embodiment of the present disclosure.

FIG. 10 illustrates an example of a light reception signal according to the second embodiment of the present disclosure.

FIG. 11 illustrates an example of a processing procedure of abnormality detection processing according to the second embodiment of the present disclosure.

FIG. 12A illustrates an example of a light reception signal according to a third embodiment of the present disclosure.

FIG. 12B illustrates an example of a light reception signal according to the third embodiment of the present disclosure.

FIG. 13 illustrates an example of a processing procedure of abnormality detection processing according to the third embodiment of the present disclosure.

FIG. 14 illustrates a configuration example of a light source according to a fourth embodiment of the present disclosure.

FIG. 15 illustrates an example of a light emission method of the light source according to the fourth embodiment of the present disclosure.

FIG. 16 illustrates an example of a processing procedure of abnormality detection processing according to the fourth embodiment of the present disclosure.

FIG. 17 illustrates a configuration example of a light emitting device according to a variation of the embodiment of the present disclosure.

FIG. 18 illustrates a configuration example of the light emitting device according to the variation of the embodiment of the present disclosure.

FIG. 19 illustrates a configuration example of the light emitting device according to the variation of the embodiment of the present disclosure.

FIG. 20 illustrates a configuration example of a distance measuring device to which the technology according to the present disclosure can be applied.

FIG. 21 illustrates an example of a processing procedure of processing performed by the distance measuring device to which technology according to the present disclosure can be applied.

FIG. 22 illustrates an example of a processing procedure of threshold correction processing performed by the distance measuring device to which the technology according to the present disclosure can be applied.

### DESCRIPTION OF EMBODIMENTS

Embodiments of the present disclosure will be described in detail below with reference to the drawings. The description will be given in the following order. Note that, in each of the following embodiments, the same reference signs are attached to the same parts to omit duplicate description.
1. First Embodiment
2. Second Embodiment
3. Third Embodiment
4. Fourth Embodiment
5. Variation
6. Application Example

### 1. First Embodiment

### Configuration of Light Emitting Device

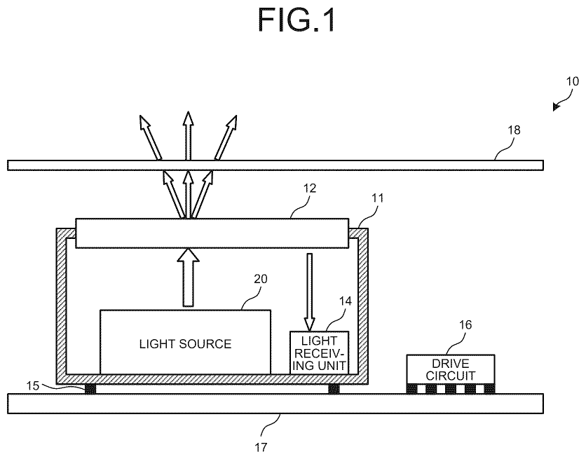

FIG. 1 illustrates a configuration example of a light emitting device according to a first embodiment of the present disclosure. The figure is a cross-sectional view illustrating a configuration example of a light emitting device 10. The light emitting device 10 includes a light source 20, and emits light. The light source 20 includes, for example, a vertical cavity surface emitting laser (VCSEL). The light source 20 is arranged on a bottom plate of a housing 11. The housing 11 is made of metal and the like. The housing 11 protects the light source 20, and blocks light from the light source 20. Wiring for transmitting signals and the like from the light source 20 and a light receiving unit 14 to be described later is formed on the bottom plate of the housing 11. The wiring can be connected to the light source 20 and the light receiving unit 14 by, for example, wire bonding.

Furthermore, a diffusion plate 12 is arranged on a top plate of the housing 11. The diffusion plate 12 converts light from the light source 20 into diffused light. Arrows in the figure indicate light emitted from the light source 20 and diffused by the diffusion plate 12. The light receiving unit 14 is further arranged on the bottom plate of the housing 11. The light receiving unit 14 receives light from the light source 20. The figure illustrates the light receiving unit 14 receiving light reflected by the diffusion plate 12 or the like.

The housing 11 in which the light source 20 and the like are arranged is mounted on a substrate 17. The housing 11 is connected to the wiring of the substrate 17 via terminals 15 arranged on the bottom surface. A drive circuit 16 is further mounted on the substrate 17. The drive circuit 16 is configured by housing an electronic circuit that drives the light source 20 and the like in a semiconductor package. The drive circuit 16 in the figure is connected to the wiring of the substrate 17 via the terminals at the bottom. Furthermore, a protective glass plate 18 is arranged above the housing 11.

### Configuration of Light Source

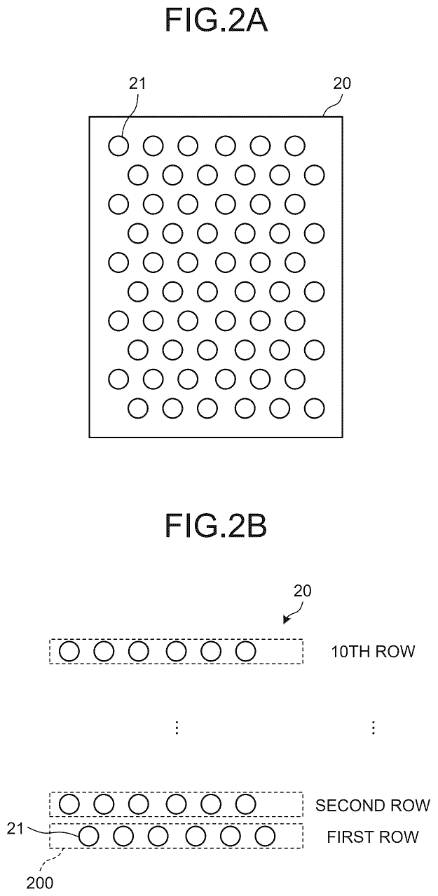

FIGS. 2A and 2B illustrate configuration examples of the light source according to the first embodiment of the present disclosure. FIG. 2A is a plan view illustrating a configuration example of the light source 20. The light source 20 includes a plurality of light emitting units 21. A circle in the figure represents a light emitting unit 21. The figure illustrates an example of the light source 20 including a VCSEL. The light emitting units 21 that vertically emit laser light are arranged in an array. The figure illustrates an example of the light source 20 in which the light emitting units 21 are arranged in 10 rows and 6 columns.

FIG. 2B illustrates an example in which the plurality of light emitting units 21 of the light source 20 is divided into a plurality of regions 200. A dotted rectangle in the figure represents a range of a region 200. The figure illustrates an example in which a region 200 is allocated to each of rows of the plurality of light emitting units 21 arranged in the light source 20. The light source 20 in the figure is divided into 10 regions 200 of the first to 10th rows. A plurality of light emitting units 21 included in a region 200 is simultaneously driven to emit light.

### Configuration of Light Emitting Device

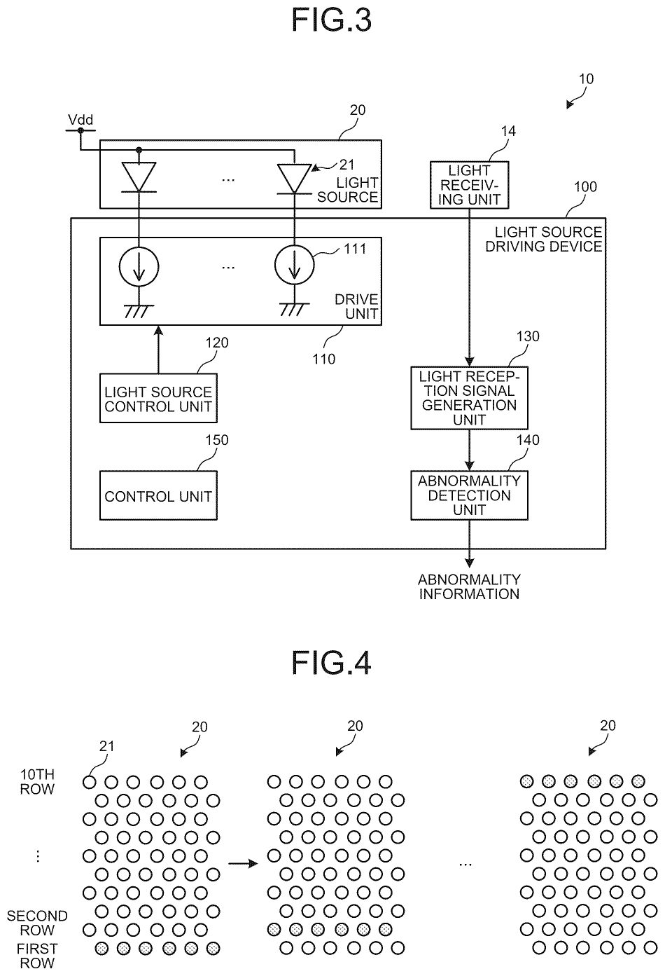

FIG. 3 illustrates a configuration example of the light emitting device according to the embodiment of the present disclosure. The figure is a block diagram illustrating a configuration example of the light emitting device 10. The light emitting device 10 includes the light source 20, the light receiving unit 14, and a light source driving device 100.

The light source 20 includes the plurality of light emitting units 21 as described above. The light source 20 can include, for example, a VCSEL. Furthermore, the light emitting units 21 of the light source 20 can emit light for each of the above-described regions 200.

The light receiving unit 14 receives light from the light source 20 as described above. The light receiving unit 14 includes, for example, a photodiode, and outputs current in accordance with an amount of received light. As illustrated in FIG. 1, the light receiving unit 14 can be arranged adjacent to the light source 20.

The light source driving device 100 drives the light source 20. Furthermore, the light source driving device 100 detects abnormality of the light source 20. The light source driving device 100 includes a drive unit 110, a light source control unit 120, a light reception signal generation unit 130, an abnormality detection unit 140, and a control unit 150.

The drive unit 110 drives the light emitting units 21 of the light source 20. The drive unit 110 causes the light emitting units 21 to emit light by causing current equal to or larger than a threshold to flow through the light emitting units 21. The figure illustrates an example of the drive unit 110 including a plurality of constant current circuits 111 each connected to each of the light emitting units 21. Light emission and non-light emission of the light emitting units 21 can be switched between by controlling current of the constant current circuits 111.

The light source control unit 120 controls the light source 20. The light source control unit 120 controls light emission of the light emitting units 21 of the light source 20 by controlling driving of the drive unit 110. The light source control unit 120 performs control to cause a light emitting units 21 to emit light for each of the above-described regions 200.

The light reception signal generation unit 130 generates a light reception signal based on current from the light receiving unit 14. For example, an analog-to-digital converter can be used as the light reception signal generation unit 130. The light reception signal is output to the abnormality detection unit 140.

The abnormality detection unit 140 detects abnormality of the light source 20 based on the light reception signal. The abnormality detection unit 140 can detect abnormality for each of the regions 200 of the light source 20. Abnormality can be detected by comparing the light reception signal with a threshold. The abnormality detection unit 140 holds an upper limit threshold and a lower limit threshold for each of the regions 200. When the light reception signal deviates from a range between the upper limit threshold and the lower limit threshold, the abnormality detection unit 140 can detect abnormality. When detecting abnormality, the abnormality detection unit 140 outputs abnormality information to an external device. The abnormality information includes information on the position of a region 200 having abnormality.

The control unit 150 controls the entire light source driving device 100. The control unit 150 can control selection of a region of the light source 20, light emission of the selected region, and abnormality detection of the selected region.

### Light Emission of Light Source

FIG. 4 illustrates an example of a light emission method of the light source according to the first embodiment of the present disclosure. The figure illustrates an example of the light emission method of the light emitting units 21 in the light source 20. In the figure, as in FIG. 2B, a region 200 is allocated to each row. A described “first row” and the like represent corresponding regions 200. Furthermore, the light emitting units 21 hatched in the figure are emitting light. The light source control unit 120 performs control to cause the light emitting units 21 to emit light in order from the first row. In the case, the position of a row in which light is emitted is sequentially moved in the light source 20. The light receiving unit 14 sequentially receives light for each row from the light source 20. Next, the light reception signal generation unit 130 generates a light reception signal, and sequentially outputs the light reception signal to the abnormality detection unit 140. The abnormality detection unit 140 detects abnormality by comparing a light reception signal for each row with a threshold.

### Threshold of Light Reception Signal

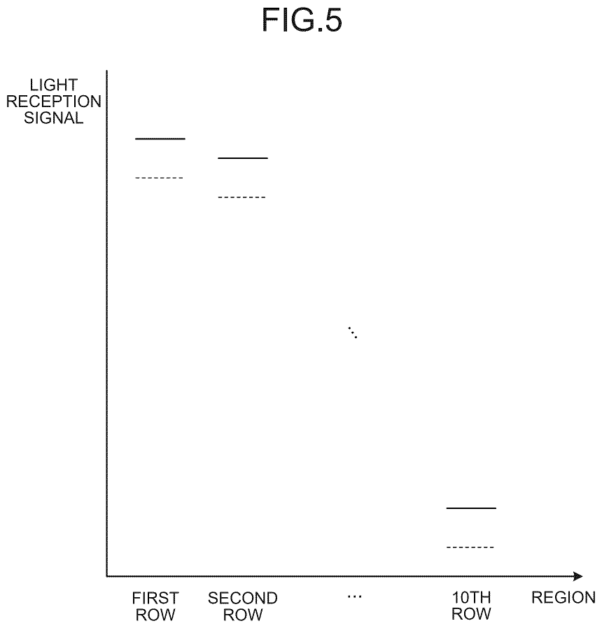

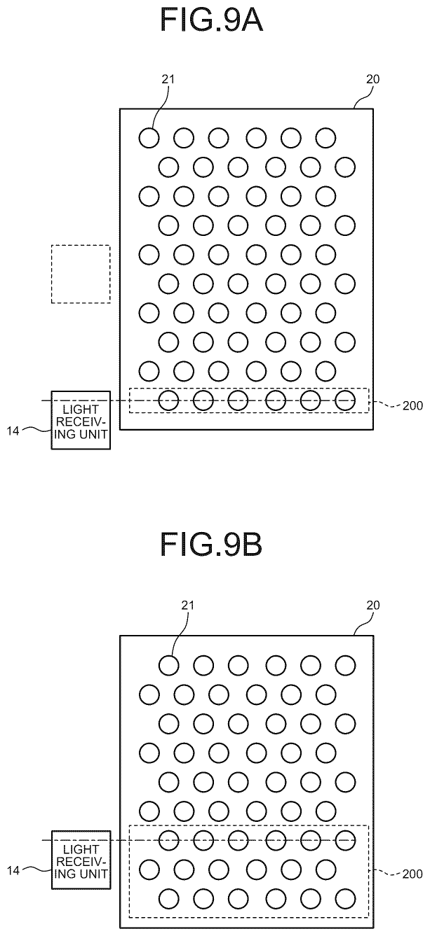

FIG. 5 illustrates an example of the threshold according to the first embodiment of the present disclosure. The figure illustrates an example of a threshold of a light reception signal in the abnormality detection unit 140. In the figure, the vertical axis represents a light reception signal. The light reception signal corresponds to the amount of received light in the light receiving unit 14. The horizontal axis in the figure represents the position of a region. In the figure, solid lines represent upper limit thresholds, and dotted lines represent lower limit thresholds. The figure illustrates a range of the threshold in a case where the light receiving unit 14 is arranged in the vicinity of the first row represented in FIG. 9A to be described later. A threshold corresponding to the first row is the highest.

When the light reception signal has a value between the lower limit threshold and the upper limit threshold, the abnormality detection unit 140 determines that the light emitting units 21 in the corresponding region are normal. In contrast, when the light reception signal has a value less than the lower limit threshold or the light reception signal has a value exceeding the upper limit threshold, the abnormality detection unit 140 determines that the light emitting units 21 in the corresponding region are abnormal. The case where the light reception signal has a value less than the lower limit threshold corresponds to, for example, a case where the light emitting unit 21 does not emit light due to damage. Furthermore, the case where the light reception signal has a value exceeding the upper limit threshold corresponds to, for example, a case where the amount of received light is increased by irregular reflection from a crack caused by damage of the light source 20, the diffusion plate 12, and the like.

### Abnormality Detection Processing

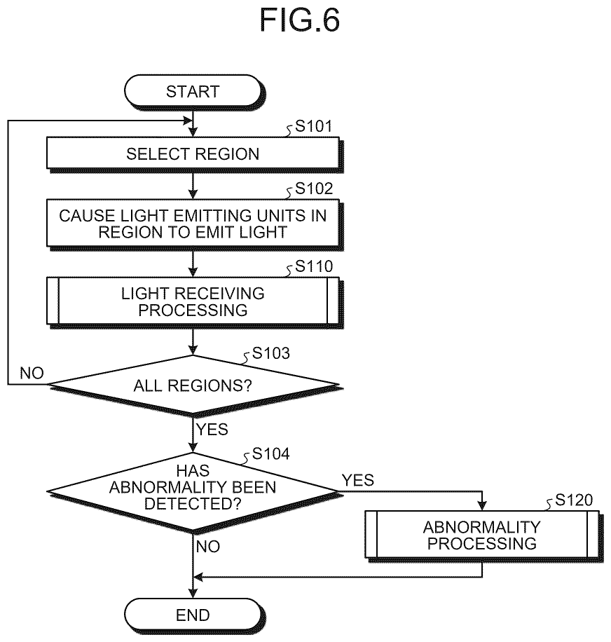

FIG. 6 illustrates an example of a processing procedure of abnormality detection processing according to the first embodiment of the present disclosure. The figure is a flowchart illustrating an example of a processing procedure of abnormality detection processing in the light source driving device 100. First, the control unit 150 selects a region of the light source 20 (Step S101). Next, the light source control unit 120 causes the light emitting units 21 in the selected region 200 to emit light (Step S102). Next, the light source driving device 100 performs light receiving processing (Step S110). Next, the control unit 150 determines whether all the regions 200 have been selected (Step S103). When not all the regions 200 have been selected (Step S103, No), the control unit 150 returns to the processing of Step S101, and selects another region 200.

In contrast, when all the regions 200 have been selected (Step S103, Yes), the control unit 150 determines whether the abnormality detection unit 140 has detected abnormality (Step S104). When the abnormality detection unit 140 has not detected abnormality (Step S104, No), the control unit 150 ends the processing. In contrast, when the abnormality detection unit 140 has detected abnormality (Step S104, Yes), the control unit 150 executes the abnormality detection processing (Step S120), and ends the processing.

### Light Receiving Processing

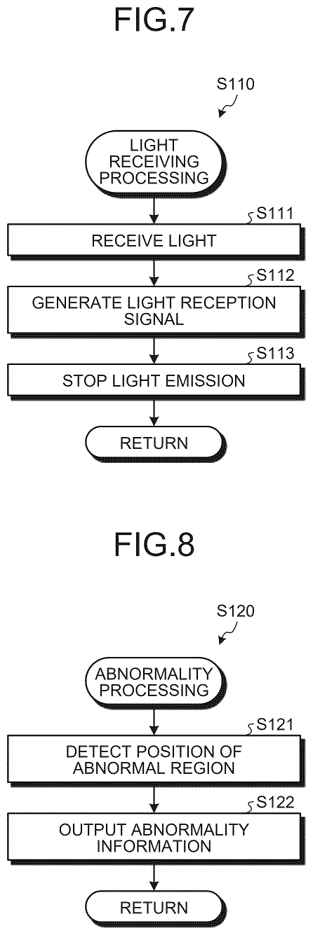

FIG. 7 illustrates an example of a processing procedure of light receiving processing according to the first embodiment of the present disclosure. The figure is a flowchart illustrating an example of a processing procedure of light receiving processing in the light source driving device 100, and illustrates the light receiving processing (Step S110) in FIG. 6. First, the light receiving unit 14 receives light from the light source 20 (Step S111). Next, the light reception signal generation unit 130 generates a light reception signal (Step S112). Next, the light source control unit 120 stops light emission of the light emitting units 21 (Step S113). Thereafter, the control unit 150 returns to the original processing.

### Abnormality Processing

FIG. 8 illustrates an example of a processing procedure of abnormality processing according to the first embodiment of the present disclosure. The figure is a flowchart illustrating an example of a processing procedure of abnormality processing in the light source driving device 100, and illustrates the abnormality processing (Step S120) in FIG. 6. First, the abnormality detection unit 140 detects the position of an abnormal region (Step S121). The detection can be performed by holding the position of a region 200 at the time when the abnormality detection unit 140 detects abnormality. The position of the region 200 at the time when the abnormality is detected can be acquired by a notification from the control unit 150.

Next, the abnormality detection unit 140 generates abnormality information based on the position of the detected abnormal region, and outputs the abnormality information (Step S122). Thereafter, the control unit 150 returns to the original processing.

As described above, the light emitting device 10 according to the first embodiment of the present disclosure detects abnormality for each of the regions 200 by causing the light emitting units 21 to emit light for each of the regions 200 and generate light reception signals. This enables detection of partial abnormality of the light source 20. For example, when a light amount of the light source 20 is insufficient, it can be determined whether the cause is aging of the light emitting units 21 and the like or partial damage of the light source 20.

### 2. Second Embodiment

In the light emitting device 10 of the first embodiment as described above, the light receiving unit 14 is arranged in the vicinity of the light source 20. In contrast, limitation of the position of the light receiving unit 14 is proposed in the light emitting device 10 of the second embodiment of the present disclosure.

### Arrangement of Light Receiving Unit

FIGS. 9A and 9B illustrate arrangement examples of the light receiving unit according to the second embodiment of the present disclosure. The figure is a plan view illustrating an example of the arrangement of the light receiving unit 14.

The light receiving unit 14 of the second embodiment of the present disclosure can be arranged at positions having different optical path lengths from the plurality of regions 200 of the light source 20. For example, the light receiving unit 14 can be arranged at a position close to a region 200 at an end of the light source 20 and separated from a region 200 at other than the end of the light source 20.

FIG. 9A illustrates an example of a case where light emitting units 21 in one row are allocated to a region 200. In the figure, the light receiving unit 14 can be arranged adjacent to a side surface of the light source 20. The light receiving unit 14 can be arranged at a position where the light receiving unit 14 partially overlaps a center line of the region 200 at a lower end of the light source 20 in the figure and does not overlap a center line of a region 200 at other than the lower end.

FIG. 9B illustrates an example of a case where light emitting units 21 in three rows are allocated to a region 200. As in FIG. 9A, the light receiving unit 14 can be arranged at a position where the light receiving unit 14 partially overlaps a center line of the region 200 at a lower end of the light source 20 in the figure and does not overlap a center line of a region 200 at other than the lower end.

As described above, light reception signals can be changed for each of the regions 200 by arranging the light receiving unit 14 at positions having different optical path lengths from the plurality of regions 200 of the light source 20. When the region 200 close to the light receiving unit 14 emits light, the light reception signals increase, and the light reception signals decrease as a region 200 is separated from the light receiving unit 14. The position of a region 200 can be identified based on the change of the light reception signals.

In contrast, when the light receiving unit 14 is arranged at a symmetrical position in upper and lower regions 200 as indicated by a rectangle of a broken line in FIG. 9A, identification of the position of a region 200 based on a change of light reception signals is difficult.

### Light Reception Signal

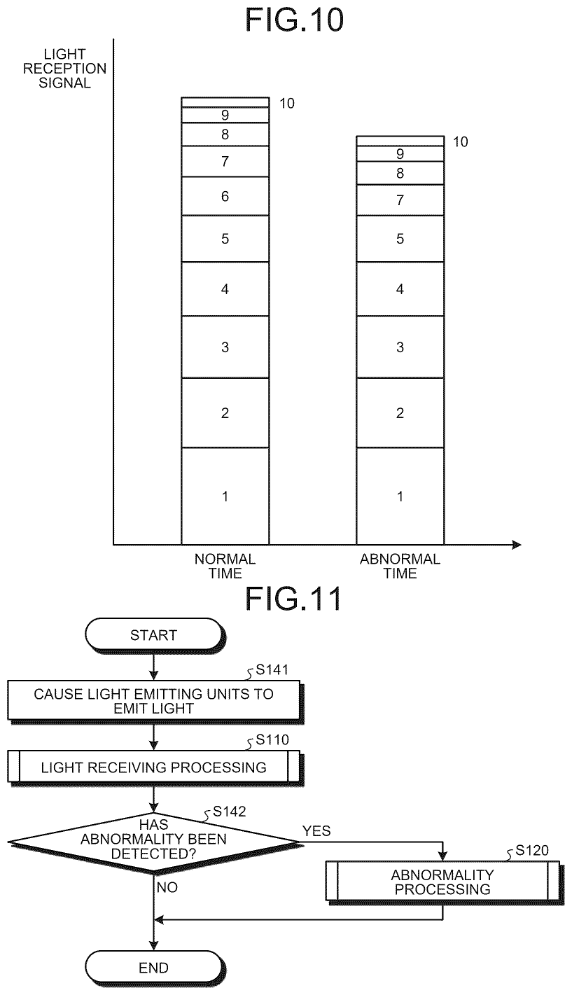

FIG. 10 illustrates an example of a light reception signal according to the second embodiment of the present disclosure. The figure illustrates an example of light reception signals in a case where all the light emitting units 21 of the light source 20 emit light. In the figure, the vertical axis represents a light reception signal. Rectangles in the figure represent light reception signals for each of the regions 200. The numbers attached to the rectangles represent the numbers of rows of the light source 20. At normal time, light reception signals of the first to 10th rows are integrated and detected. As illustrated in the figure, the light receiving unit 14 is arranged at positions having different optical path lengths from the plurality of regions 200 of the light source 20, so that the light reception signals of the first to 10th rows have different values.

In contrast, at abnormal time, light reception signals of a region 200 that does not emit light due to abnormality are reduced, and light reception signals after integration are reduced. The figure illustrates an example of a case where the sixth row has abnormality. The position of a row (region 200) in an abnormal state can be identified by detecting the difference between light reception signals at the normal time and the abnormal time.

### Abnormality Detection Processing

FIG. 11 illustrates an example of a processing procedure of abnormality detection processing according to the second embodiment of the present disclosure. Similarly to FIG. 6, the figure is a flowchart illustrating an example of a processing procedure of abnormality detection processing in the light source driving device 100. First, the control unit 150 causes all the light emitting units 21 of the light source 20 to emit light (Step S141). Next, the light source driving device 100 performs light receiving processing (Step S110). Next, the control unit 150 determines whether the abnormality detection unit 140 has detected abnormality (Step S142). When the abnormality detection unit 140 has not detected abnormality (Step S142, No), the control unit 150 ends the processing.

In contrast, when the abnormality detection unit 140 has detected abnormality (Step S142, Yes), the control unit 150 executes the abnormality detection processing (Step S120). In the abnormality detection processing, the abnormality detection unit 140 detects the position of an abnormal region by comparing the light reception signals with the light reception signals at the normal time. Thereafter, the control unit 150 ends the processing.

Not as in the abnormality detection processing in FIG. 6, light emission of the light source 20 and detection of light reception signals are performed only once in the abnormality detection processing in the figure.

The other configuration of the light emitting device 10 is similar to the configuration of the light emitting device 10 in the first embodiment of the present disclosure, so that the description thereof will be omitted.

As described above, the light emitting device 10 of the second embodiment of the present disclosure can shorten the processing by arranging the light receiving unit 14 at positions having different optical path lengths from the plurality of regions 200 of the light source 20 and detecting abnormality.

### 3. Third Embodiment

The light emitting device 10 of the second embodiment as described above performs light emission of the light source 20 and detection of light reception signals only once. In contrast, a light emitting device 10 of a third embodiment of the present disclosure is different from that in the above-described second embodiment in that the light emission of the light source 20 and the detection of light reception signals are performed a plurality of times.

As described above, the light emitting device 10 of the third embodiment of the present disclosure performs the light emission of the light source 20 and the detection of light reception signals a plurality of times. In the plurality of times of light emissions of the light source 20, the light emitting device 10 adjusts an amount of emitted light for each of the regions 200.

### Light Reception Signal

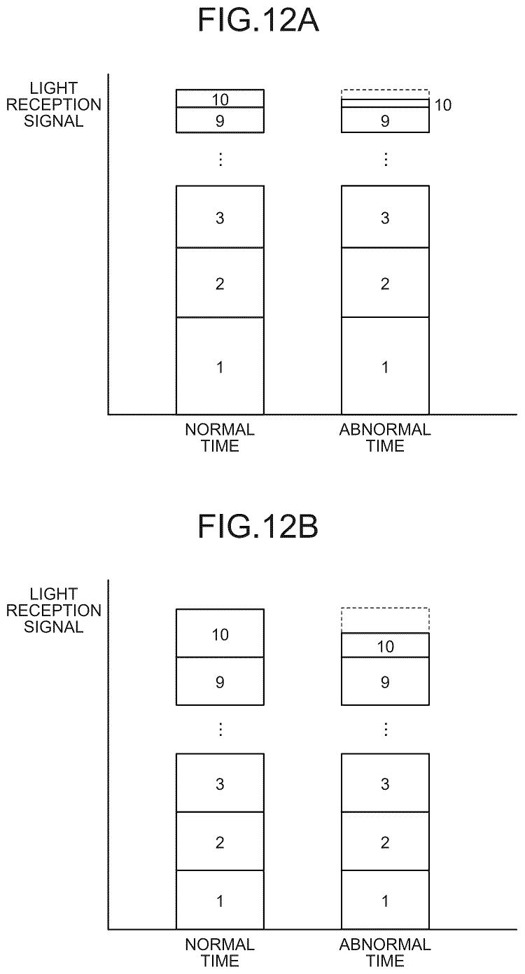

FIGS. 12A and 12B illustrate examples of light reception signals according to the third embodiment of the present disclosure. Similarly to FIG. 10, the figures illustrate examples of light reception signals. FIG. 12A illustrates a light emission pattern in which all the light emitting units 21 of the light source 20 emit light in the same light amount. The light emission pattern in the figure is referred to as a first light emission pattern.

FIG. 12B illustrates a light emission pattern in which light reception signals of all the rows (regions 200) of the light source 20 are aligned. In this case, light emission currents of the light emitting units 21 have different values for each row. The light emission pattern in the figure is referred to as a second light emission pattern.

Note that FIGS. 12A and 12B illustrate examples of values at abnormal time, in which a light amount is reduced by 50% due to damage of a part of light emitting units 21 in the 10th row.

In the first light emission pattern, if the ratios of light reception signals in the first to 10th rows are set as 10 to 1, the ratio to light reception signals at the normal time is 55. In contrast, a change of light reception signals at the abnormal time is 0.5, and the ratio to the light reception signals at the normal time is 0.5/55.

In the second light emission pattern, if light reception signals in the first to 10th rows have the same ratio, a change of the light reception signals at the abnormal time is 5, and the ratio to the light reception signals at the normal time is 5/100. As described above, the ratio between the first light emission pattern and the second light emission pattern is 1:4.5. Since the ratio identifies the 10th row, the row can be identified as a position of a region 200 where a light emitting unit 21 is damaged.

### Abnormality Detection Processing

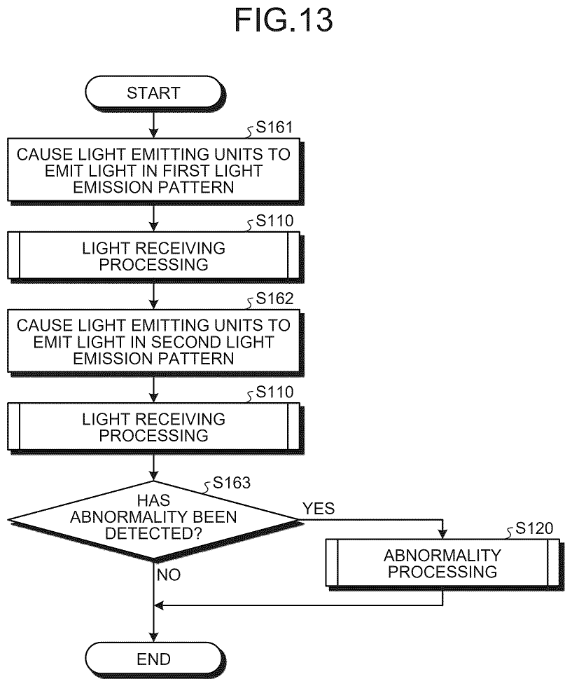

FIG. 13 illustrates an example of a processing procedure of abnormality detection processing according to the third embodiment of the present disclosure. Similarly to FIG. 11, the figure is a flowchart illustrating an example of a processing procedure of abnormality detection processing in the light source driving device 100. First, the control unit 150 causes light emitting units 21 to emit light in the first light emission pattern (Step S161). Next, the light source driving device 100 performs light receiving processing (Step S110). Next, the control unit 150 causes light emitting units 21 to emit light in the second light emission pattern (Step S162). Next, the light source driving device 100 performs light receiving processing again (Step S110). Next, the control unit 150 determines whether the abnormality detection unit 140 has detected abnormality (Step S163). When the abnormality detection unit 140 has not detected abnormality (Step S163, No), the control unit 150 ends the processing.

In contrast, when the abnormality detection unit 140 has detected abnormality (Step S163, Yes), the control unit 150 executes the abnormality detection processing (Step S120). In the abnormality detection processing, the abnormality detection unit 140 performs arithmetic operations for the light reception signals in the first light emission pattern and the light reception signals in the second light emission pattern, and detects the position of an abnormal region. Thereafter, the control unit 150 ends the processing.

Not as in the abnormality detection processing in FIG. 11, light emission of the light source 20 and detection of light reception signals are performed twice in the abnormality detection processing in the figure.

The other configuration of the light emitting device 10 is similar to the configuration of the light emitting device 10 in the second embodiment of the present disclosure, so that the description thereof will be omitted.

As described above, the light emitting device 10 of the third embodiment of the present disclosure acquires a plurality of light reception signals in different light emission patterns, and identifies the position of an abnormal region by performing an arithmetic operation for the light reception signals. This enables detection of the position of an abnormal region even in a case of a small change of the light reception signals due to abnormality.

### 4. Fourth Embodiment

In the light emitting device 10 of the first embodiment as described above, the light emission of the light emitting unit 21 is controlled for each of the regions 200 in the light source 20. In contrast, a light emitting device 10 of a fourth embodiment of the present disclosure is different from that of the above-described first embodiment in that light emission is controlled for each of light emission groups including a plurality of regions 200.

### Configuration of Light Source

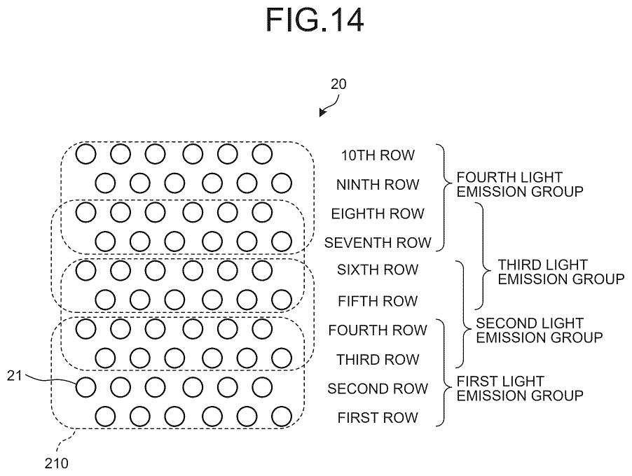

FIG. 14 illustrates a configuration example of a light source according to a fourth embodiment of the present disclosure. Similarly to FIG. 2B, the figure illustrates a configuration example of the light source 20. As in FIG. 2B, regions 200 are set for each row in the light source 20 in the figure.

Light emission of the light emitting units 21 in the figure is controlled for each of light emission groups 210 including a plurality of regions 200. A region indicated by a broken line in the figure represents a range of a light emission group 210. The figure illustrates an example of a light emission group 210 including four regions 200. A plurality of light emitting units 21 included in a light emission group 210 is simultaneously driven to emit light.

Furthermore, a light emission group 210 in the figure shares a partial region 200 with an adjacent light emission group 210. A first light emission group in the figure includes regions 200 of the first to fourth rows. Furthermore, a second light emission group includes regions 200 of the third to sixth rows. Furthermore, a third light emission group includes regions 200 of the fifth to eighth rows. Furthermore, a fourth light emission group includes regions 200 of the seventh to 10th rows. As described above, a light emission group 210 in the figure shares two regions 200 with adjacent light emission groups.

### Light Emission of Light Source

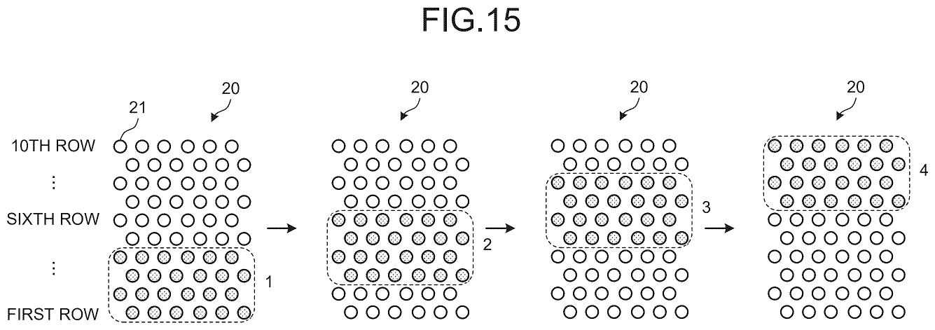

FIG. 15 illustrates an example of a light emission method of the light source according to the fourth embodiment of the present disclosure. Similarly to FIG. 4, the figure illustrates an example of the light emission method of the light emitting units 21 in the light source 20. In the description in the figure, “1” and the like represent the numbers of corresponding light emission groups 210. Furthermore, the light emitting units 21 hatched in the figure are emitting light. The light source control unit 120 causes light emitting units 21 to emit light in order from the first light emission group. The position of the light emission group 210 emitting light in the light source 20 is sequentially moved. The light receiving unit 14 sequentially receives light for each of the light emission groups 210 from the light source 20. The light reception signal generation unit 130 generates light reception signals, and sequentially outputs the light reception signals to the abnormality detection unit 140. The abnormality detection unit 140 performs an arithmetic operation for a light reception signal for each of the light emission groups 210, and detects abnormality.

For example, it is assumed that there is a light emission defect in the sixth row in the figure. The light emission defect changes (decreases) light reception signals of the second and third light emission groups. In the second light emission group, a region 200 of the sixth row is most separated from the light receiving unit 14, so that a change of light reception signals in the second light emission group is relatively small. In contrast, a region 200 of the sixth row is close to the light receiving unit 14 in the third light emission group, so that a change of light reception signals in the third light emission group is relatively large. Therefore, the position of a region 200 having abnormality can be identified by comparing the changes of the light reception signals of the light emission groups 210 with each other.

### Abnormality Detection Processing

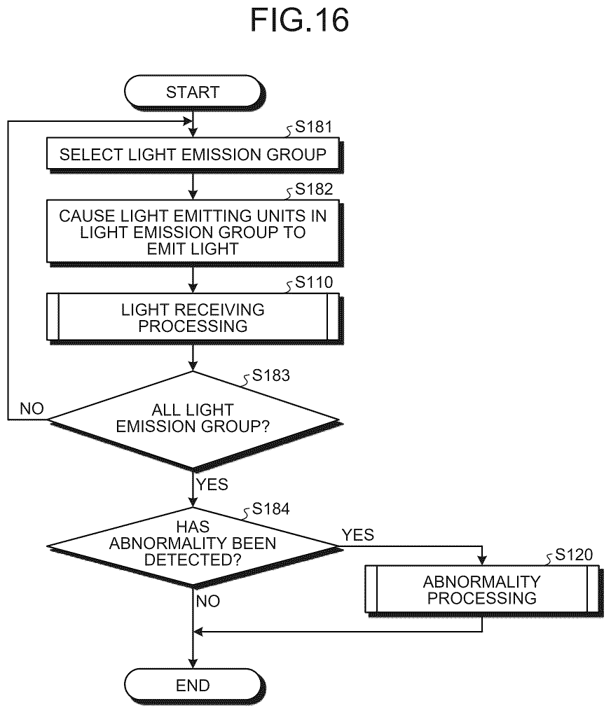

FIG. 16 illustrates an example of a processing procedure of abnormality detection processing according to the fourth embodiment of the present disclosure. Similarly to FIG. 6, the figure is a flowchart illustrating an example of a processing procedure of abnormality detection processing in the light source driving device 100. First, the control unit 150 selects a light emission group 210 (Step S181). Next, the light source control unit 120 causes light emitting units 21 in the selected light emission group 210 to emit light (Step S182). Next, the light source driving device 100 performs light receiving processing (Step S110). Next, the control unit 150 determines whether all the light emission groups 210 have been selected (Step S183). When not all the light emission groups 210 have been selected (Step S183, No), the control unit 150 returns to the processing of Step S181, and selects another light emission group 210.

In contrast, when all the light emission groups 210 have been selected (Step S183, Yes), the control unit 150 determines whether the abnormality detection unit 140 has detected abnormality (Step S184). When the abnormality detection unit 140 has not detected abnormality (Step S184, No), the control unit 150 ends the processing.

In contrast, when the abnormality detection unit 140 has detected abnormality (Step S184, Yes), the control unit 150 executes the abnormality detection processing (Step S120). In the abnormality detection processing, the abnormality detection unit 140 detects the position of an abnormal region by comparing the changes of the light reception signals for each of the light emission groups 210 with each other. Thereafter, the control unit 150 ends the processing.

Not as in the abnormality detection processing in FIG. 6, light emission of the light source 20 and detection of light reception signals are performed four times in the abnormality detection processing in the figure.

The other configuration of the light emitting device 10 is similar to the configuration of the light emitting device 10 in the first embodiment of the present disclosure, so that the description thereof will be omitted.

As described above, the light emitting device 10 of the fourth embodiment of the present disclosure causes light emitting units 21 to emit light for each of a plurality of light emission groups 210 to generate light reception signals, and identifies the position of an abnormal region by comparing changes of the light reception signals with each other. This can shorten the processing.

### 5. Variation

A variation of the light emitting device 10 of the first embodiment as described above will be described.

### Configuration of Light Emitting Device

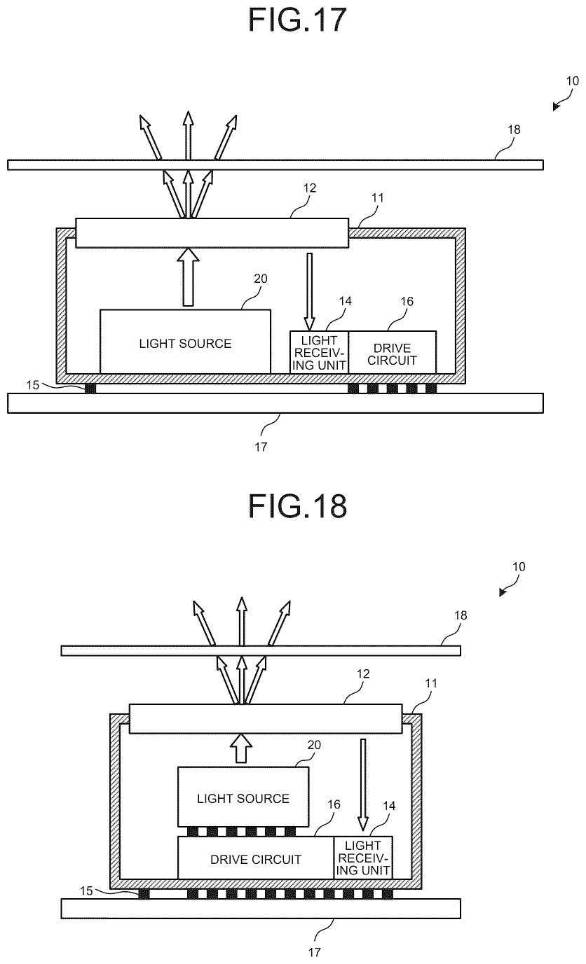

FIGS. 17 to 19 illustrate configuration examples of a light emitting device according to the variation of the embodiment of the present disclosure. FIG. 17 is a cross-sectional view illustrating a configuration example of the light emitting device 10. The figure illustrates an example of the light emitting device 10 in which the drive circuit 16 and the light receiving unit 14 are formed on the same semiconductor substrate and arranged in the housing 11. FIG. 18 illustrates an example in which the light source 20 and the drive circuit 16 are stacked. Such configuration can downsize the light emitting device 10.

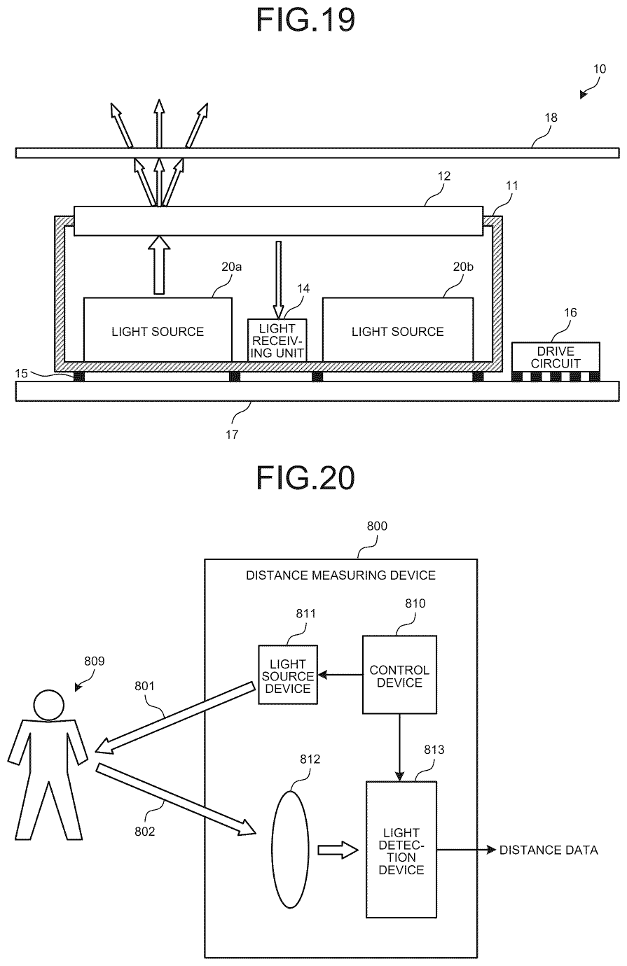

FIG. 19 illustrates an example of the light emitting device 10 including two light sources 20 (light source 20a and light source 20b). When one of the light sources 20a and 20b is damaged, the light source can be switched to the other light source 20 for use. The light emitting device 10 in the figure is assumed to be used as, for example, an on-vehicle light emitting device.

### 6. Application Example

The light emitting device 10 of the embodiment as described above can be applied to various products. An example in which the light emitting device 10 is applied to a distance measuring device will be described.

FIG. 20 illustrates a configuration example of a distance measuring device to which the technology according to the present disclosure can be applied. The figure is a block diagram illustrating a configuration example of a distance measuring device 800. The distance measuring device 800 includes a light detection device 813, a control device 810, a light source device 811, and an imaging lens 812. The distance measuring device 800 measures a distance to an object. The figure further illustrates an object 809.

The light source device 811 emits light. The light source device 811 applies emitted light 801 to the object 809 at the time of measuring a distance. For example, a light emitting diode that emits infrared light can be used for the light source device 811.

The imaging lens 812 collects light from the object 809 to the light detection device 813. The imaging lens 812 in the figure collects reflected light 802, which is obtained by the emitted light 801 being reflected by the object 809, to the light detection device 813.

The light detection device 813 detects the reflected light 802 from the object 809, and measures a distance to the object 809. The light detection device 813 includes a sensor and a processing circuit. The sensor detects the reflected light 802. The processing circuit performs distance measuring processing. In the distance measuring processing, a time from emission of the emitted light 801 performed by the light source device 811 to detection of the reflected light 802 is measured, and a distance to the object 809 is measured based on the measured time from emission of the emitted light 801 to detection of the reflected light 802. The measured distance to the object 809 is output to an external device as distance data.

The control device 810 controls the entire distance measuring device 800. At the time of measuring a distance, the control device 810 performs control in which the light source device 811 is controlled so as to emit the emitted light 801 and the light detection device 813 is controlled so as to start time measurement and measure a distance.

The light emitting device 10 in FIG. 1 can be applied to a light source device 811 in the figure.

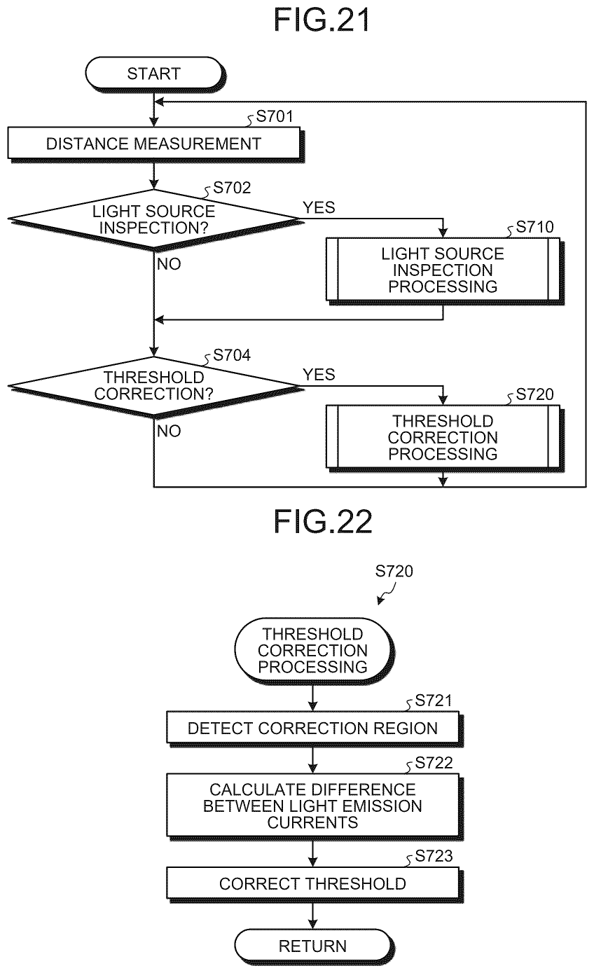

FIG. 21 illustrates an example of a processing procedure of processing performed by a distance measuring device to which technology according to the present disclosure can be applied. The figure is a flowchart illustrating an example of a processing procedure of a distance measuring device 800. First, the distance measuring device 800 performs the above-described distance measurement (Step S701). Next, the distance measuring device 800 determines whether or not to inspect the light source device 811 (Step S702). The determination can be made by determining whether a periodic inspection time has come, for example. In Step S702, when the light source inspection is not performed (Step S702, No), the processing proceeds to Step S704.

In contrast, when the light source inspection is performed in Step S702 (Step S702, Yes), the distance measuring device 800 executes light source inspection processing (Step S710), and proceeds to processing of Step S704. For example, the processing in FIG. 6 can be applied to the light source inspection processing.

In Step S704, the distance measuring device 800 determines whether to perform threshold correction (Step S704). The determination can be made by determining whether a periodic threshold correction time has come, for example. In Step S704, when the threshold correction is not performed (Step S704, No), the processing proceeds to Step S701.

In contrast, when the threshold correction is performed in Step S704 (Step S704, Yes), the distance measuring device 800 executes processing of threshold correction processing (Step S720), and proceeds to processing of Step S701.

FIG. 22 illustrates an example of a processing procedure of threshold correction processing performed by the distance measuring device to which the technology according to the present disclosure can be applied. The figure is a flowchart illustrating an example of a processing procedure of the threshold correction processing in FIG. 21, and illustrates processing executed by the light source driving device 100 in FIG. 3. First, the control unit 150 detects a correction region of a light emitting unit 21 (Step S721). The detection can be performed by detecting a region where a light reception signal in the light emitting unit 21 of the light source 20 exceeds a range between an upper limit threshold and a lower limit threshold. Next, the control unit 150 calculates the difference between light emission currents of light emitting units 21 in the detected region (Step S722). The calculation can be performed by calculating the difference between light emission current falling within a range between the upper limit threshold and the lower limit threshold and current light emission current. Next, the control unit 150 corrects a threshold (Step S723). The correction can be performed by adjusting a threshold of light emission based on the difference between light emission currents calculated in Step S722.

Note that a light emitting unit 21, which has not been determined to be abnormal in the light source inspection processing due to a small change of light reception signals, can be determined to have been deteriorated. Such a light emitting unit 21 can be corrected by the threshold correction processing.

Although the embodiments of the present disclosure have been described above, the technical scope of the present disclosure is not limited to the above-described embodiments as it is, and various modifications can be made without departing from the gist of the present disclosure. Furthermore, components of different embodiments and variations may be appropriately combined.

Note that the effects described in the present specification are merely examples and not limitations. Other effects may be obtained.

Note that the present technology can also have the configurations as follows.
(1) A light source driving device comprising:
   a light source control unit that performs control in which a plurality of light emitting units is divided into a plurality of regions in a light source in which the plurality of light emitting units is arranged, and the light emitting units are caused to emit light for each of the regions; and
   an abnormality detection unit that detects abnormality of the light emitting units for each of the regions based on a light reception signal from a light receiving unit that generates the light reception signal in accordance with light from the light source.
(2) The light source driving device according to the above (1), wherein the light receiving unit is arranged at positions having different optical path lengths from the plurality of regions.
(3) The light source driving device according to the above (2), wherein the light receiving unit is arranged adjacent to the light source, and arranged at a position close to a region at an end of the light source and separated from a region at other than the end of the light source.
(4) The light source driving device according to the above (2) or (3),
   wherein the light source control unit controls a first light emission pattern in which light is emitted with light amounts of the plurality of light emitting units being aligned and a second light emission pattern in which light is emitted with light reception signals from the plurality of light emitting units being aligned, and
   the abnormality detection unit detects the abnormality based on the light reception signals in the first light emission pattern and the second light emission pattern.
(5) The light source driving device according to the above (2) or (3),
   wherein the light source control unit performs control in which the light emitting units are caused to emit light for each of light emission groups including a plurality of regions, and
   the abnormality detection unit detects abnormality of the light emitting units for each of the light emission groups. (6) The light source driving device according to the above (5), wherein the light source control unit performs control in which the light emitting units are caused to emit light for each of adjacent light emission groups sharing a partial region.
(7) A light emitting device comprising:
   a light source in which a plurality of light emitting units is arranged;
   a light source control unit that performs control in which the plurality of light emitting units is divided into a plurality of regions in the light source and the light emitting units are caused to emit light for each of the regions;
   a light receiving unit that generates a light reception signal in accordance with light from the light source; and
   an abnormality detection unit that detects abnormality of the light emitting units for each of the regions based on the light reception signal.

### REFERENCE SIGNS LIST

10 LIGHT EMITTING DEVICE
14 LIGHT RECEIVING UNIT
20, 20a, 20b LIGHT SOURCE
21 LIGHT EMITTING UNIT
100 LIGHT SOURCE DRIVING DEVICE
120 LIGHT SOURCE CONTROL UNIT
130 LIGHT RECEPTION SIGNAL GENERATION UNIT
140 ABNORMALITY DETECTION UNIT
200 REGION
210 LIGHT EMISSION GROUP

1. A light source driving device comprising:
a light source control unit that performs control in which a plurality of light emitting units is divided into a plurality of regions in a light source in which the plurality of light emitting units is arranged, and the light emitting units are caused to emit light for each of the regions; and
an abnormality detection unit that detects abnormality of the light emitting units for each of the regions based on a light reception signal from a light receiving unit that generates the light reception signal in accordance with light from the light source.

2. The light source driving device according to claim 1, wherein the light receiving unit is arranged at positions having different optical path lengths from the plurality of regions.

3. The light source driving device according to claim 2, wherein the light receiving unit is arranged adjacent to the light source, and arranged at a position close to a region at an end of the light source and separated from a region at other than the end of the light source.

4. The light source driving device according to claim 2,
wherein the light source control unit controls a first light emission pattern in which light is emitted with light amounts of the plurality of light emitting units being aligned and a second light emission pattern in which light is emitted with light reception signals from the plurality of light emitting units being aligned, and
the abnormality detection unit detects the abnormality based on the light reception signals in the first light emission pattern and the second light emission pattern.

5. The light source driving device according to claim 2,
wherein the light source control unit performs control in which the light emitting units are caused to emit light for each of light emission groups including a plurality of regions, and
the abnormality detection unit detects abnormality of the light emitting units for each of the light emission groups.

6. The light source driving device according to claim 5, wherein the light source control unit performs control in which the light emitting units are caused to emit light for each of adjacent light emission groups sharing a partial region.

7. A light emitting device comprising:
a light source in which a plurality of light emitting units is arranged;
a light source control unit that performs control in which the plurality of light emitting units is divided into a plurality of regions in the light source and the light emitting units are caused to emit light for each of the regions;
a light receiving unit that generates a light reception signal in accordance with light from the light source; and
an abnormality detection unit that detects abnormality of the light emitting units for each of the regions based on the light reception signal.
